(19) United States
(12) Patent Application Publication
(10) Pub. No.: US 2025/0304434 A1
(43) Pub. Date: Oct. 2, 2025

(54) ACTUATOR LAYER DEPOSITION AND TRANSFER

(71) Applicant: InvenSense, Inc., San Jose, CA (US)

(72) Inventors: Jotaro Akiyama, Yamanashi Prefecture (JP); Yoshitaka Sasaki, Uniondale, NY (US); Yuki Shibano, Tokyo (JP); Daishi Arimatsu, Yamanashi-ken (JP); Kento Kaneko, Yamanashi-ken (JP); Kenichi Tohchi, Yamanashi prefecture (JP)

(21) Appl. No.: 18/623,442

(22) Filed: Apr. 1, 2024

(51) Int. Cl. B81C 1/00

(52) U.S. Cl. CPC B81C 1/00888; B81C 2201/0183; B81C 2201/0192

(57) ABSTRACT

A method includes forming a dielectric layer on a carrier wafer with a top surface and a bottom surface, wherein the top surface is positioned opposite to the bottom surface. The method includes forming a cleave layer on the dielectric layer that covers the top surface of the carrier wafer. Method includes forming a silicon Oxide layer (SiO₂) over the cleave layer and coupling the Si layer to a handle wafer, wherein the handle wafer comprises silicon and wherein the handle wafer includes at least one cavity, wherein the Si layer encloses the at least one cavity. The method includes separating the carrier wafer from the handle wafer, wherein the separating forms a first wafer and a second wafer, wherein the first wafer comprises the handle wafer and the Si layer and a portion of the cleave layer, and wherein the second wafer is a reusable carrier wafer.

### BACKGROUND

Motion sensors may be created using a class of devices known as MEMS (“micro-electro-mechanical systems”) and may be fabricated using semiconductor-like processes and exhibit mechanical characteristics. For example, MEMS devices may include the ability to move or deform. In many cases, but not always, MEMS interact with electrical signals. A MEMS device may refer to a semiconductor device that is implemented as a micro-electro-mechanical system. A MEMS device includes mechanical elements and may optionally include electronics (e.g., electronics for sensing). MEMS devices include but are not limited to, for example, gyroscopes, accelerometers, magnetometers, pressure sensors, microphone, etc.

Actuator layer of the MEMS device may be created by depositing silicon or poly-silicon routed substrate. Unfortunately, forming a MEMS device by depositing silicon or poly-silicon may require release holes to be placed the proof mass. Moreover, other limitations of depositing silicon or poly-silicon routed substrate is to allow for thermal budgeting because heat that is being applied throughout the process adversely impacts the circuitry, e.g., complementary metal-oxide-semiconductor (CMOS), application specific integrated circuit (ASIC), etc. In some conventional systems, use of release holes or having to account for thermal budgeting is eliminated by creating the actuator layer by thinning a wafer after the fusion bond process. The thinning process, unfortunately, consumes a wafer and therefore increases the cost of fabrication.

### SUMMARY

Accordingly, a need has arisen to form the actuator layer of a motion sensor without consideration for thermal budgeting, without having to sacrifice a wafer, and further without having to form release holes in the proof mass. In some embodiments, the actuator layer is formed by using a carrier wafer that is reusable again after the process is complete. A dielectric layer such as a thermal oxide, SiN, SiO₂, etc., is deposited (formed) on the carrier wafer. The carrier wafer may comprise silicon or poly-silicon. A cleave layer is deposited on the dielectric layer. Subsequently, a silicon layer is formed over the cleave layer such that a silicon wafer comprising handle and an actuator layer can couple to the carrier wafer. The carrier wafer is subsequently separated from the handle wafer, thereby forming two wafers, one wafer being the handle wafer and the other wafer being the carrier wafer that is reusable.

A method includes forming a dielectric layer on a carrier wafer, e.g., comprising silicon, glass, etc., with a top surface and a bottom surface. The top surface is positioned opposite to the bottom surface. The method further includes forming a cleave layer, e.g., Titanium (Ti) or Tungsten (W), on the dielectric layer that covers the top surface of the carrier wafer. In one nonlimiting example, the method further includes forming a silicon layer (Si) over the cleave layer. According to some embodiments, the method further includes coupling the Si layer to a handle wafer. The handle wafer comprises silicon and the handle wafer includes at least one cavity in one nonlimiting example. It is appreciated that the coupling may be fusion bonding the Si layer to an oxide layer of the handle wafer in one nonlimiting example. It is appreciated that the handle layer may be lined with oxide before coupling. The Si layer encloses the at least one cavity. The method also includes separating the carrier wafer from the handle wafer. It is appreciated that the separating forms a first wafer and a second wafer. The first wafer comprises the handle wafer and the Si layer and a portion of the cleave layer. The second wafer is a reusable carrier wafer.

In some embodiments, the reusable carrier wafer comprises the carrier wafer, the dielectric layer and a second portion of the cleave layer. According to some nonlimiting examples, the method further includes forming a silicon dioxide (SiO₂) layer directly on the cleave layer and patterning the SiO₂ layer to expose at least one region of the cleave layer. It is appreciated that in one nonlimiting example the Si layer is formed directly over the patterned SiO₂ layer. The method may further include forming Si layer directly on the at least one region to form a standoff in the first wafer. In some embodiments, the method further includes forming a plurality of bump patterns on the patterned SiO₂ layer and before forming the Si layer over the patterned SiO₂ layer.

It is appreciated that in some embodiments, the method may further include removing the first portion of the cleave layer from the first wafer and removing the SiO₂ layer from the first wafer, subsequent to the separating the carrier wafer from the handle wafer. According to some embodiments, the separating includes shining an infrared light onto the handle wafer and the carrier wafer after the Si layer is coupled to the handle wafer. In some embodiments, the separating may include shining a visible light onto the handle wafer and the carrier wafer after the Si layer is coupled to the handle wafer, wherein the shining weakens the cleave layer, and subsequently mechanically cleaving the first wafer from the second wafer.

In one nonlimiting example, the method includes forming a thermal oxide layer on a carrier wafer, e.g., silicon or glass, with a top surface and a bottom surface. The top surface is positioned opposite to the bottom surface. The method further includes forming a cleave layer, e.g., Titanium (Ti) or Tungsten (W), on the thermal oxide layer that covers the top surface of the carrier wafer. According to some embodiments, the method further includes forming a silicon dioxide (SiO₂) layer directly on the cleave layer and patterning the SiO₂ layer to expose at least one region of the cleave layer. The method further includes forming a silicon layer (Si) over the at least one region of the cleave layer and further over the patterned SiO₂ layer. It is appreciated that in one nonlimiting example, the method further includes coupling the Si layer to a handle wafer. According to some embodiments, the handle wafer comprises silicon and wherein the handle wafer includes at least one cavity. According to one nonlimiting example the Si layer encloses the at least one cavity. In some nonlimiting examples, the method also includes separating the carrier wafer from the handle wafer. It is appreciated that the separating forms a first wafer and a second wafer where the first wafer comprises the handle wafer and the Si layer and the patterned SiO₂ layer and a first portion of the cleave layer. The second wafer comprises the thermal oxide layer and a second portion of the cleave layer.

It is appreciated that the method may further include forming a plurality of bump patterns on the patterned SiO₂ layer and before forming the Si layer over the patterned SiO₂ layer. In yet some embodiments, the method may further include removing the first portion of the cleave layer from the first wafer and removing the SiO₂ layer from the first wafer subsequent to the separating the carrier wafer from the handle wafer. The silicon layer covering the at least one region forms a standoff region on the first wafer. According to one nonlimiting example, the separating may include shining an infrared light onto the handle wafer and the carrier wafer after the Si layer is coupled to the handle wafer where the shining weakens the cleave layer and subsequently mechanically cleaving the first wafer from the second wafer. According to some embodiments, the separating includes shining a visible light onto the handle wafer and the carrier wafer to weaken the cleave layer where the shining is subsequent to the Si layer being coupled to the handle wafer. The separating is complete by mechanically cleaving the first wafer from the second wafer.

In one nonlimiting example, a method includes forming a thermal oxide layer on a carrier wafer with a top surface and a bottom surface, wherein the top surface is positioned opposite to the bottom surface. The method also includes forming a cleave layer on the thermal oxide layer that covers the top surface of the carrier wafer. In one nonlimiting example, the method also includes forming a silicon layer (Si) over the cleave layer and forming a handle layer. The method further includes attaching a second carrier layer to a second side of the handle layer. In one nonlimiting example, the method includes separating the carrier wafer from the handle wafer. The separating forms a first wafer and a second wafer, where the first wafer comprises the handle wafer and the Si layer and a portion of the cleave layer, and where the second wafer is a reusable carrier wafer.

In some nonlimiting examples, the method may further include forming first silicon dioxide (SiO₂) layer, the silicon layer and a sacrificial silicon dioxide directly over the cleave layer. According to some embodiments, the method further includes patterning the sacrificial SiO₂ layer and depositing polysilicon layer over the silicon layer, etching release holes in the polysilicon layer, and removing the sacrificial Silicon dioxide layer and depositing the handle layer.

In some embodiments, the method may further include patterning the Silicon layer to form standoffs. According to some embodiments, the method further includes depositing Ge on the standoff and eutectic bonding to a silicon substrate. According to one nonlimiting example, the method includes removing the second carrier layer using light irradiation after the bonding.

These and other features and advantages will be apparent from a reading of the following detailed description.

### BRIEF DESCRIPTION OF DRAWINGS

FIGS. 1-4 show a temporal carrier wafer in various stages of a fabrication process according to one aspect of the present embodiments.

FIGS. 5A-5C show forming a patterned SiO₂ layer over the temporal carrier wafer according to some aspects of the present embodiments.

FIG. 6 shows forming a silicon layer over the temporal carrier wafer according to one aspect of the present embodiments.

FIG. 7 shows coupling a handle layer to the temporal carrier wafer according to one aspect of the present embodiments.

FIG. 8 shows separating the handle layer from the temporal carrier wafer according to one aspect of the present embodiments.

FIG. 9 shows removing the cleave layer and the patterned SiO₂ layer from the handle layer and according to one aspect of the present embodiments.

FIGS. 10-17 show a fabrication method by depositing the handle layer on the actuator layer according to one aspect of the present embodiments.

FIG. 18 shows an example of a flow diagram for fabricating a sensor device using a temporal carrier wafer according to one aspect of the present embodiments.

FIG. 19 shows another example of a flow diagram for fabricating a sensor device using a temporal carrier wafer according to one aspect of the present embodiments.

FIG. 20 shows an example of a flow diagram for fabricating a sensor device by depositing the handle layer on the actuator layer according to one aspect of the present embodiments.

### DESCRIPTION

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein.

It should also be understood that the terminology used herein is for the purpose of describing the certain concepts, and the terminology is not intended to be limiting. Unless defined otherwise, all technical and scientific terms used herein have the same meaning as commonly understood in the art to which the embodiments pertain.

Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “middle,” “bottom,” “beside,” “forward,” “reverse,” “overlying,” “underlying,” “up,” “down,” or other similar terms such as “upper,” “lower,” “above,” “below,” “under,” “between,” “over,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Terms such as “over,” “overlying,” “above,” “under,” etc. are understood to refer to elements that may be in direct contact or may have other elements in-between. For example, two layers may be in overlying contact, wherein one layer is over another layer and the two layers physically contact. In another example, two layers may be separated by one or more layers, wherein a first layer is over a second layer and one or more intermediate layers are between the first and second layers, such that the first and second layers do not physically contact.

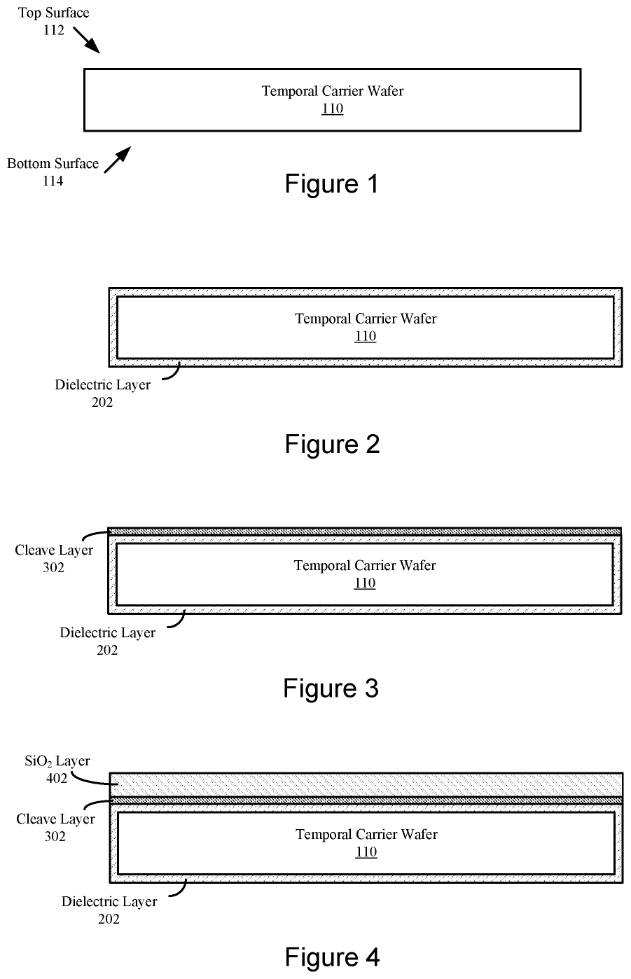

FIGS. 1-4 show a temporal carrier wafer in various stages of a fabrication process according to one aspect of the present embodiments. In FIG. 1, a temporal carrier wafer 110 has a top surface 112 and a bottom surface 114 that are opposite from one another. In other words, the top surface 112 faces away from the bottom surface 114. In one nonlimiting example, the temporal carrier wafer 110 is a substrate formed from silicon. In yet another nonlimiting example, the temporal carrier wafer 110 is a substrate formed from glass.

Referring now to FIG. 2, a dielectric layer 202 is formed over the temporal carrier wafer 110. In one nonlimiting example, the dielectric layer 202 may form over the top surface 112 and the bottom surface 114 of the temporal carrier wafer 110 while in some nonlimiting examples, the dielectric layer 202 may encompass the sides of the temporal carrier wafer 110, as illustrated. The dielectric layer 202 may be a thermal oxide layer in one nonlimiting example. In yet another nonlimiting example, the dielectric layer 202 may be SiN or SiO₂ and may be deposited using chemical vapor deposition (CVD) or sputtering. In one nonlimiting example, the dielectric layer 202 may be patterned.

Referring now to FIG. 3, a cleave layer 302 is formed over the dielectric layer 202. In one nonlimiting example, the cleave layer 302 is formed on the side of the top surface 112 of the temporal carrier wafer 110, by covering the dielectric layer 202 that is deposited on the top surface 112 of the temporal carrier wafer 110. It is appreciated that the cleave layer 302 may comprise Titanium (Ti) or Tungsten. In one nonlimiting example, the cleave layer 302 may be patterned.

Referring now to FIG. 4, a silicon Oxide (SiO₂) layer 402 is formed over the cleave layer 302. The silicon layer 402 may include Si in combination with other material. In one nonlimiting example, the silicon layer 402 includes SiO₂ but it may include other materials as well. It is appreciated that in some embodiments, the SiO₂ layer 402 is formed directly over the cleave layer 302. However, it is appreciated in some other embodiments, the SiO₂ layer 402 is formed over other layers that are positioned between the SiO₂ layer 402 and the cleave layer 302. It is appreciated that the SiO₂ layer 402 may be planarized by going through chemical mechanical polishing (CMP). It is appreciated that in some embodiments, the cleave layer 302 may partially become exposed by a trim patterning process and further by applying a photoresist, performing deep reactive ion etching (DRIE), and removing the photoresist.

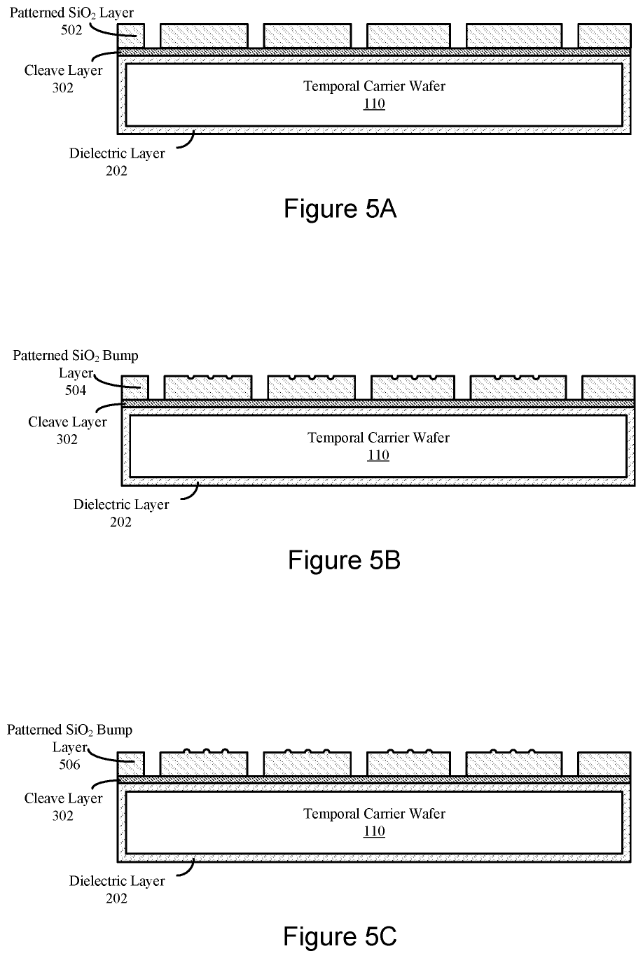

Referring now to FIG. 5A, the SiO₂ layer 402 is patterned to form a patterned SiO₂ layer 502. In one nonlimiting example, lithography may be used to pattern the SiO₂ layer 402 to form the patterned SiO₂ layer 502. In some embodiments, a mask may be formed over the SiO₂ layer 402 and patterned and the SiO₂ layer 402 may subsequently be etched (portions that are not covered by the patterned mask) in order to form the patterned SiO₂ layer 502. It is appreciated that patterning the SiO₂ layer 402 exposes at least one region of the cleave layer 302.

In some optional embodiments, a plurality of patterned bumps may be formed over the patterned SiO₂ layer 502 of FIG. 5A, as shown in FIG. 5B, to reduce stiction. In FIG. 5B, the patterned SiO₂ bump layer 504 is formed. In one nonlimiting example, the patterned SiO₂ bump layer 504 is formed using buffer oxide etch (BOE) wet etch. In this nonlimiting example, the bumps form indentation within the patterned SiO₂ layer 502.

In some optional embodiments, a plurality of patterned bumps may be formed over the patterned SiO₂ layer 502 of FIG. 5A, as shown in FIG. 5C, to reduce stiction. In FIG. 5C, the patterned SiO₂ bump layer 506 is formed. In one nonlimiting example, the patterned SiO₂ bump layer 506 is formed via a thermal oxidation process where polysilicon is oxidized and as a result becomes rough. In this nonlimiting example, the bumps extrudes out of the patterned SiO₂ layer 502.

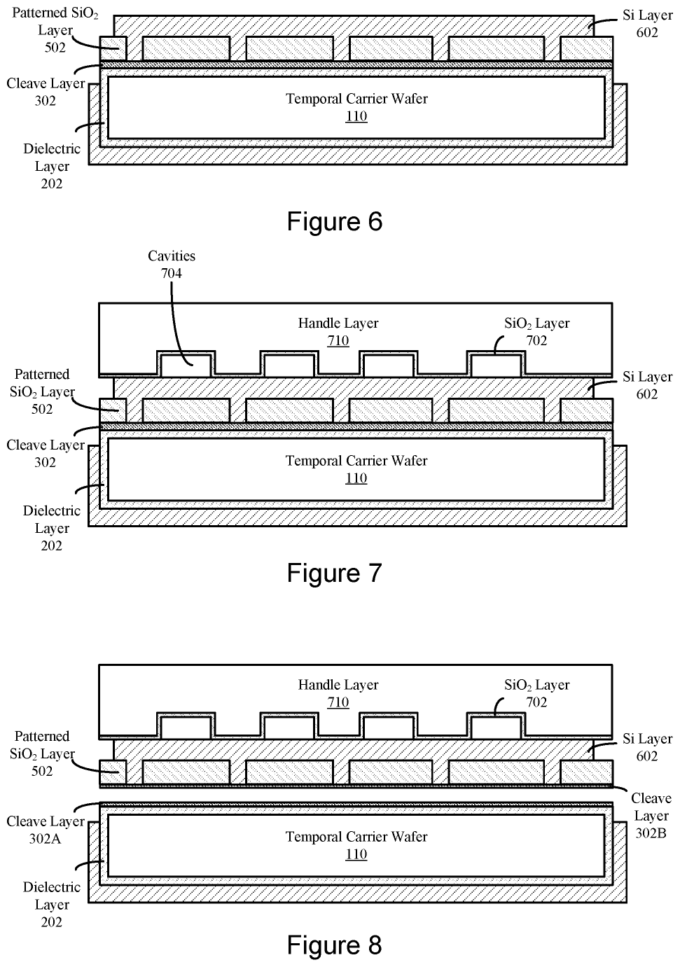

For illustration purposes, the rest of the process is described with respect to FIG. 5A but should not be construed as limiting the scope of the embodiments. For example, the following processes are equally applicable to FIGS. 5B and 5C. Referring now to FIG. 6, a silicon layer 602 is deposited over the patterned SiO₂ layer 502. Forming the silicon layer 602 over the patterned SiO₂ layer 502 also deposits the silicon layer 602 on exposed portions of the cleave layer 302. In some embodiments, the silicon layer 602 is formed directly over the patterned SiO₂ layer 502. It is appreciated that forming the silicon layer 602 directly on the region of the cleave layer 302 that is exposed forms a standoff (described later).

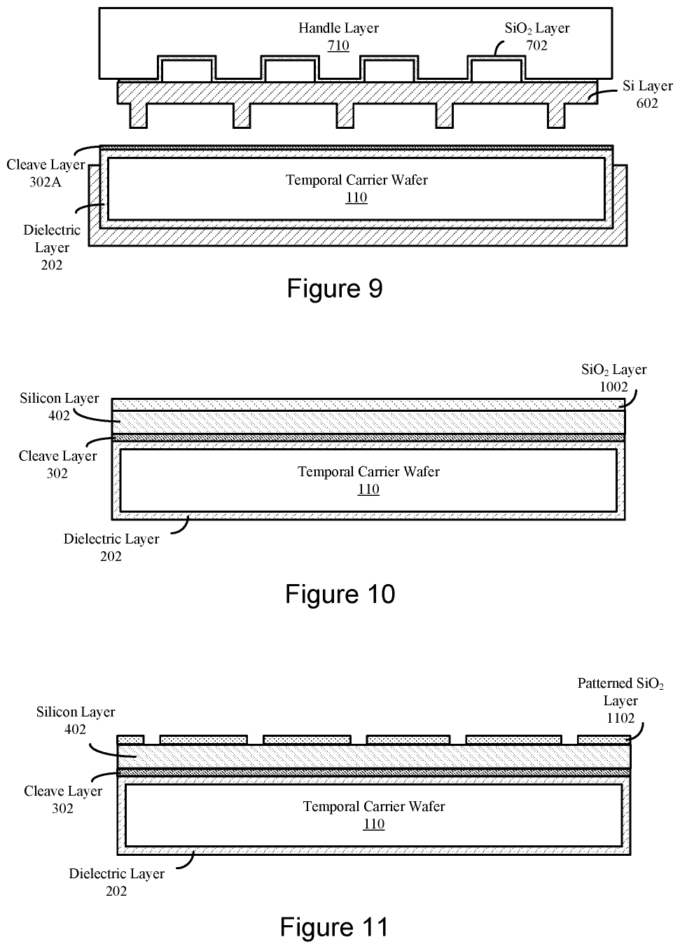

Referring now to FIG. 7, a handle layer 710 is coupled to the silicon layer 602. In one nonlimiting example, the handle layer 710 includes silicon and has at least one cavity 704. According to some embodiments, the side of the handle layer 710 that is to be coupled to the silicon layer 602 may be covered with a layer of oxide, e.g., SiO₂ layer 702. The coupling causes the silicon layer 602 to enclose the cavity 704 between the silicon layer 602 and the handle layer 710. In one nonlimiting example, the coupling of the handle layer 710 to the silicon layer 602 may be via fusion bonding the silicon layer 602 to an oxide layer 702 of the handle wafer 710 and by annealing at approximately 300 Celsius for strengthening the fusion bonding between the two.

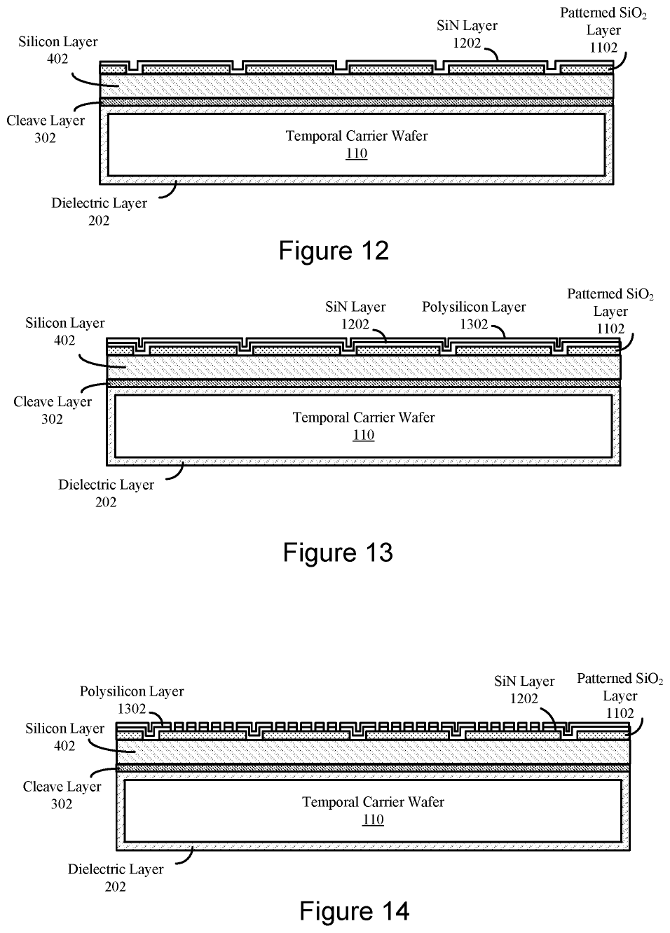

Referring now to FIG. 8, the cleave layer 302 of FIG. 7 is weakened by shinning light. For example, shining an infrared light onto the structure of FIG. 7 (e.g., the temporal carrier wafer 110 and the handle layer 710) weakens the cleave layer 302. In one nonlimiting example where the temporal carrier wafer 110 is glass a visible light may be used. Once the cleave layer 302 is weakened, the handle layer 710 may be separated from the temporal carrier wafer 110 through mechanical cleaving the handle layer 710 from the temporal carrier wafer 110. The handle layer 710 forms one wafer while the temporal carrier wafer 110 forms another wafer. The handle layer 710 on the side that was separated from the temporal carrier wafer 110 may include a cleave layer 302B (residue from original cleave layer 302) and patterned SiO₂ layer 502 that covers the silicon layer 602. The temporal carrier wafer 110 includes a cleave layer 302A (residue from original cleave layer 302) on the side of its top surface 112 (side that was separated from the handle layer 710). In other words, two wafers are formed and separated from one another, one being the handle layer 710 and the other being the temporal carrier wafer 110. It is appreciated that the temporal carrier wafer 110 with the cleave layer 302A formed on the top surface 112 is reusable. As illustrated, the handle layer 710 includes the silicon layer 602, the patterned silicon layer 502, and the cleave layer 302B while the temporal carrier wafer 110 includes the silicon layer (covering the bottom portion of the temporal carrier wafer 110 on the bottom surface 114 as well as the dielectric layer 202) as well as the cleave layer 302A. It is appreciated that the temporal carrier wafer 110 is reusable resulting in tremendous cost savings in comparison to the conventional methodology where the wafer was being discarded.

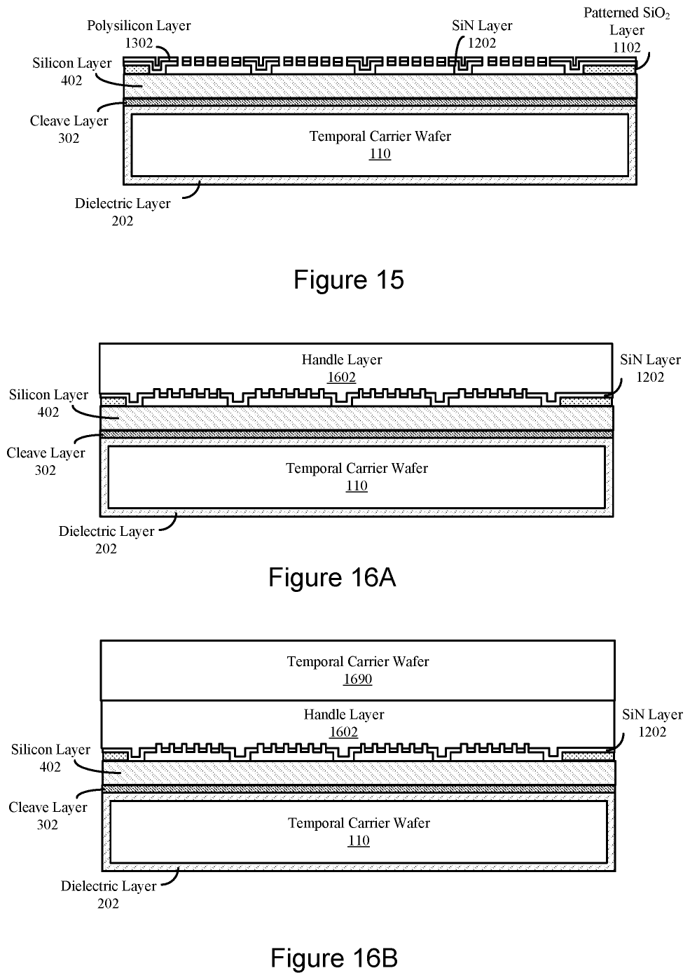

Referring now to FIG. 9, the silicon patterned SiO₂ layer 502 and the cleave layer 302B are removed, thereby exposing the silicon layer 602, which is the actuator layer of the device. As illustrated in FIG. 9, the silicon layer 602 includes at least one or more standoff that is subsequently used to couple the handle layer 710 to another wafer, e.g., CMOS. According to some embodiments, an Aluminum layer or Germanium layer may be deposited (not shown here) on the standoff of the handle layer 710 to prepare the handle layer 710 for coupling (e.g., eutectic bonding) with another wafer, e.g., CMOS. It is appreciated that in one nonlimiting example, a slight thermal oxidation may be done on the silicon layer 602 in order to roughen the surface of the actuator layer in order to reduce stiction.

As illustrated, the temporal carrier wafer is reusable, thereby reducing cost. Reducing the cost is the result of depositing actuator layer, e.g., polysilicon, and reusing the temporal carrier wafer. Moreover, the embodiments as described herein, eliminate the need to design for a release hole as well as eliminating the need for thermal budget considerations.

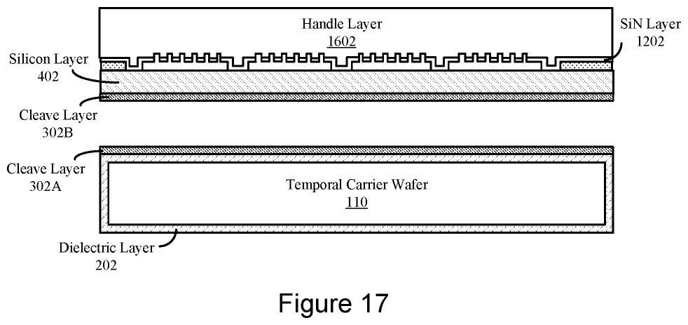

Referring now to FIGS. 10-17, a fabrication method by depositing the handle layer on the actuator layer according to one aspect of the present embodiments. It is appreciated that the steps associated with FIGS. 1-4, as described above, are performed before the process of FIG. 10. In FIG. 10, an SiO₂ layer 1002 is deposited on the silicon layer 402. In one nonlimiting example, the SiO₂ layer 1002 is deposited directly on the silicon layer 402. The SiO₂ layer 1002 may be patterned to form the patterned SiO₂ layer 1102, as shown in FIG. 11, thereby exposing at least one or more region of the silicon layer 402. Patterning the SiO₂ layer 1002 eventually forms the cavity of the device. Referring now to FIG. 12, an SiN layer 1202 is formed over the patterned SiO₂ layer 1102. In one nonlimiting example, the SiN layer 1202 is formed directly over the patterned SiO₂ layer 1102. The SiN layer 1202 act as an isolation layer between the actuator layer and the handle layer at a later stage. Referring now to FIG. 13, a polysilicon layer 1302 is formed over the SiN layer 1202. In one nonlimiting example, the polysilicon layer 1302 is formed directly over the SiN layer 1202.

Referring now to FIG. 14, the polysilicon layer 1302 is patterned to open holes (release holes). Referring now to FIG. 15, a release etch process, e.g., BOE, vapor hydrogen fluoride (vHF), etc., is performed to remove the sacrificial SiO₂ layer, thereby forming at least one cavity. Referring now to FIG. 16A, the handle layer 1602 is formed by depositing polysilicon and/or silicon layer. In one nonlimiting example, the handle layer 1602 may be coupled to another carrier wafer, e.g., carrier wafer 1690, on its second side facing away from the cavity.

Referring now to FIG. 17, the handle layer 1602 may be separated from the temporal carrier wafer 110. Similar to FIGS. 1-9, the cleave layer 302 is weakened by shinning light. For example, shining an infrared light onto the structure (e.g., the temporal carrier wafer 110 and the handle layer 1602) weakens the cleave layer 302. It one nonlimiting example where the temporal carrier wafer 110 is glass a visible light may be used. Once the cleave layer 302 is weakened, the handle layer 1602 may be separated from the temporal carrier wafer 110 through mechanical cleaving the handle layer 1602 from the temporal carrier wafer 110. The handle layer 1602 forms one wafer while the temporal carrier wafer 110 forms another wafer. The handle layer 1602 on the side that was separated from the temporal carrier wafer 110 may include a cleave layer 302B (residue from original cleave layer 302) and silicon layer 402. The temporal carrier wafer 110 includes a cleave layer 302A (residue from original cleave layer 302) on the side of its top surface 112 (side that was separated from the handle layer 1602). In other words, two wafers are formed and separated from one another, one being the handle layer 1602 and the other being the temporal carrier wafer 110. It is appreciated that the temporal carrier wafer 110 with the cleave layer 302A formed on the top surface 112 is reusable. As illustrated, the handle layer 1602 includes the silicon layer 402 and the cleave layer 302B while the temporal carrier wafer 110 includes the dielectric layer 202 as well as the cleave layer 302A. It is appreciated that the temporal carrier wafer 110 is reusable resulting in tremendous cost savings in comparison to the conventional methodology where the wafer was being discarded.

According to some embodiments, the silicon layer may be patterned to form one or more standoffs. The standoffs may be prepared for eutectic bonding to a silicon substrate by depositing Ge on the standoff. The second carrier layer may be removed using light irradiation after the bonding.

It is appreciated that similar to FIG. 9, the cleave layer 302B may be removed, thereby exposing the silicon layer 402 where the actuator layer is formed and patterned. It is appreciated that after the actuator layer is patterned, one or more standoffs may be formed and a layer of Aluminum layer or Germanium layer may be deposited (not shown here) on the standoff of the handle layer 1602 for coupling (e.g., eutectic bonding) with another wafer, e.g., CMOS. It is appreciated that the second carrier wafer (if one used to couple to the handle layer 1602 before separating the handle layer 1602 from the temporal carrier wafer 110) may be removed.

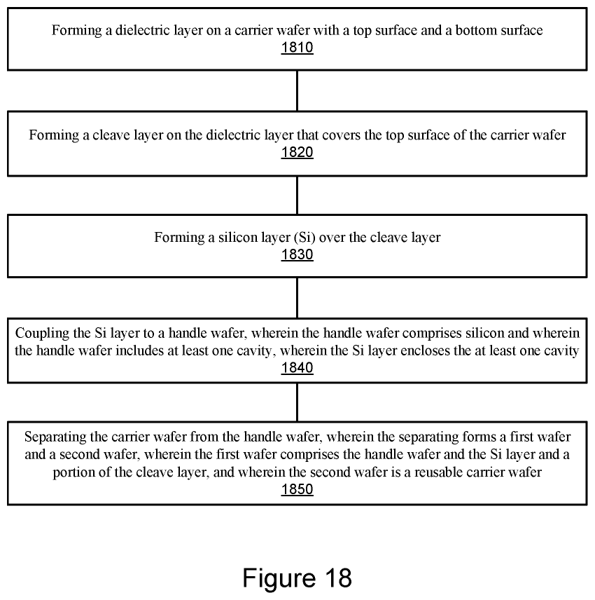

FIG. 18 shows an example of a flow diagram for fabricating a sensor device using a temporal carrier wafer according to one aspect of the present embodiments. At step 1810, a dielectric layer is formed on a carrier wafer with a top surface and a bottom surface, as described in FIGS. 1-9. The top surface is positioned opposite to the bottom surface. At step 1820, a cleave layer is formed on the dielectric layer that covers the top surface of the carrier wafer, as described in FIGS. 1-9. At step 1830, a silicon layer (Si) is formed over the cleave layer, as described above in FIGS. 1-9. At step 1840, the Si layer is coupled to a handle wafer, as described in FIGS. 1-9. The handle wafer comprises silicon and wherein the handle wafer includes at least one cavity. The Si layer encloses the at least one cavity. At step 1850, the carrier wafer is separated from the handle wafer, as described above in FIGS. 1-9. The separating forms a first wafer and a second wafer. The first wafer comprises the handle wafer and the Si layer and a portion of the cleave layer. The second wafer is a reusable carrier wafer.

As discussed above, in one nonlimiting example, the reusable carrier wafer comprises the carrier wafer, the dielectric layer and a second portion of the cleave layer. As described above, a silicon dioxide (SiO₂) layer may be formed directly on the cleave layer and patterned to expose at least one region of the cleave layer, where the Si layer is formed directly over the patterned SiO₂ layer. In one nonlimiting example, the Si layer is formed directly on the at least one region to form a standoff in the first wafer, as described above. According to some embodiments, a plurality of bump patterns may be formed on the patterned SiO₂ layer and before forming the Si layer over the patterned SiO₂ layer. In one nonlimiting example, subsequent to the separating the carrier wafer from the handle wafer, the first portion of the cleave layer is removed from the first wafer and the SiO₂ layer is removed from the first wafer. According to some embodiments, an infrared light is shined onto the handle wafer and the carrier wafer after the Si layer is coupled to the handle wafer. The cleave layer may be Titanium (Ti) or Tungsten (W). The carrier wafer may be made of silicon, glass, etc. In some embodiments, the separating may include shining a visible light onto the handle wafer and the carrier wafer after the Si layer is coupled to the handle wafer, wherein the shining weakens the cleave layer and mechanically cleaving the first wafer from the second wafer. According to some examples, the coupling may be fusion bonding the Si layer to an oxide layer of the handle wafer. In one nonlimiting example, the handle layer may be lined with oxide before coupling.

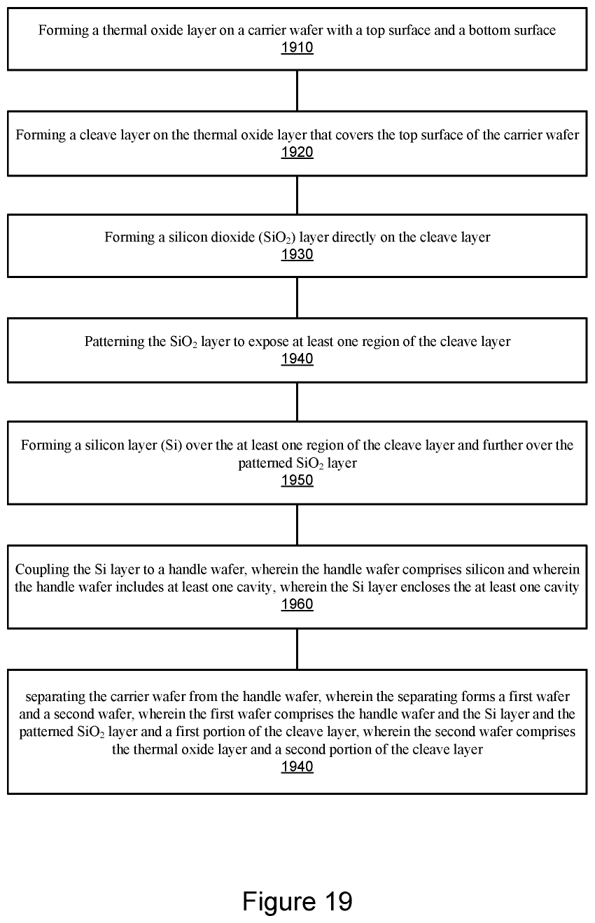

FIG. 19 shows another example of a flow diagram for fabricating a sensor device using a temporal carrier wafer according to one aspect of the present embodiments. At step 1910, a thermal oxide layer is formed on a carrier wafer with a top surface and a bottom surface, wherein the top surface is positioned opposite to the bottom surface, as described above in FIGS. 1-9. At step 1920, a cleave layer is formed on the thermal oxide layer that covers the top surface of the carrier wafer, as described above in FIGS. 1-9. At step 1930, a silicon dioxide (SiO₂) layer is formed directly on the cleave layer, as described in FIGS. 1-9. At step 1940, the SiO₂ layer is patterned to expose at least one region of the cleave layer, as described in FIGS. 1-9. At step 1950, a silicon layer (Si) is formed over the at least one region of the cleave layer and further over the patterned SiO₂ layer, as described above in FIGS. 1-9. At step 1960, the Si layer is coupled to a handle wafer, wherein the handle wafer comprises silicon and wherein the handle wafer includes at least one cavity, wherein the Si layer encloses the at least one cavity, as described above in FIGS. 1-9. At step 1970, the carrier wafer is separated from the handle wafer, wherein the separating forms a first wafer and a second wafer, wherein the first wafer comprises the handle wafer and the Si layer and the patterned SiO₂ layer and a first portion of the cleave layer, as described above in FIGS. 1-9. The second wafer comprises the thermal oxide layer and a second portion of the cleave layer.

According to some embodiments, a plurality of bump patterns is formed on the patterned SiO₂ layer and before forming the Si layer over the patterned SiO₂ layer, as described in FIGS. 1-9. In one nonlimiting example, subsequent to the separating the carrier wafer from the handle wafer, the first portion of the cleave layer is removed from the first wafer and the SiO₂ layer is removed from the first wafer, wherein the silicon layer covering the at least one region forms a standoff region on the first wafer. In some embodiments, the separating includes shining an infrared light onto the handle wafer and the carrier wafer after the Si layer is coupled to the handle wafer, wherein the shining weakens the cleave layer and mechanically cleaving the first wafer from the second wafer. It is appreciated that the cleave layer may include Titanium (Ti) or Tungsten (W). The carrier wafer may include silicon or glass. In one nonlimiting example, the separating includes shining a visible light onto the handle wafer and the carrier wafer, and wherein the shining is subsequent to the Si layer being coupled to the handle wafer, wherein the shining weakens the cleave layer and mechanically cleaving the first wafer from the second wafer.

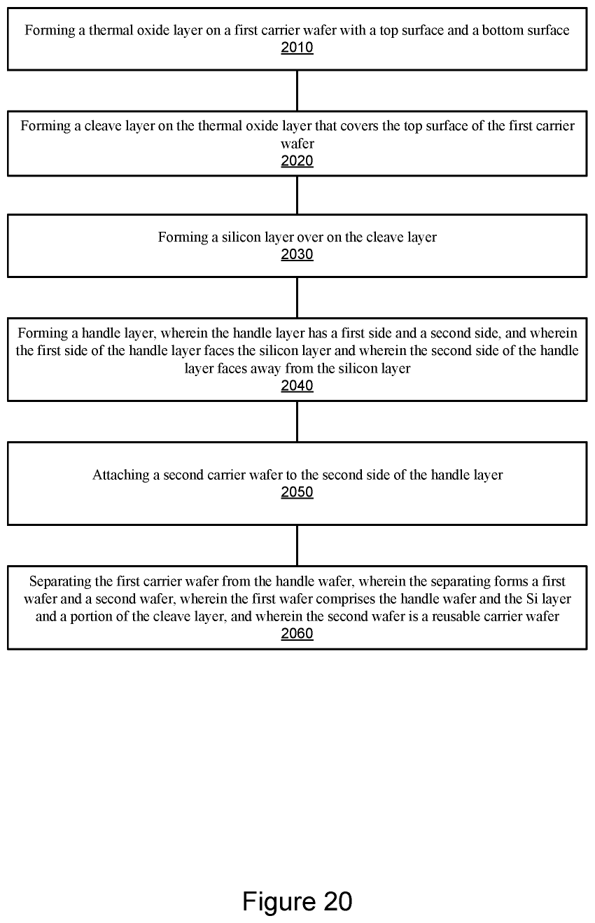

FIG. 20 shows an example of a flow diagram for fabricating a sensor device by depositing the handle layer on the actuator layer according to one aspect of the present embodiments. At step 2010, a thermal oxide layer is formed on a first carrier wafer with a top surface and a bottom surface, as described above in FIGS. 10-17. The top surface is positioned opposite to the bottom surface. At step 2020, a cleave layer is formed on the thermal oxide layer that covers the top surface of the first carrier wafer, as described above in FIGS. 10-17. At step 2030, a silicon layer (Si) is formed over the cleave layer, as described above in FIGS. 10-17. At step 2040, a handle layer is formed, as described above in FIGS. 10-17. The handle layer has a first side and a second side, where the first side of the handle layer faces the silicon layer and where the second side of the handle layer faces away from the silicon layer. At step 2050, a second carrier wafer is attached to the second side of the handle layer, as described above in FIGS. 10-17. At step 2060, the first carrier wafer is separated from the handle wafer, as described above in FIGS. 10-17. The separating forms a first wafer and a second wafer, where the first wafer comprises the handle wafer and the Si layer and a portion of the cleave layer, and where the second wafer is a reusable carrier wafer.

In one nonlimiting example, a first silicon dioxide (SiO₂) layer, the silicon layer, and a sacrificial silicon dioxide are formed directly over the cleave layer, as described above in FIGS. 10-17. According to some embodiments, the sacrificial SiO₂ layer is patterned and polysilicon layer is deposited over the silicon layer, as described above in FIGS. 10-17. In some embodiments, release holes are etched in the polysilicon layer, as described above in FIGS. 10-17. In some embodiments, the sacrificial Silicon dioxide layer is removed and the handle layer is deposited, as described above in FIGS. 10-17. According to some embodiments, the silicon layer may be patterned to form one or more standoffs. The standoffs may be prepared for eutectic bonding to a silicon substrate by depositing Ge on the standoff. The second carrier layer may be removed using light irradiation after the bonding.

While the embodiments have been described and/or illustrated by means of particular examples, and while these embodiments and/or examples have been described in considerable detail, it is not the intention of the Applicants to restrict or in any way limit the scope of the embodiments to such detail. Additional adaptations and/or modifications of the embodiments may readily appear, and, in its broader aspects, the embodiments may encompass these adaptations and/or modifications. Accordingly, departures may be made from the foregoing embodiments and/or examples without departing from the scope of the concepts described herein. The implementations described above and other implementations are within the scope of the following claims.

What is claimed is:

1. A method comprising:
forming a dielectric layer on a carrier wafer with a top surface and a bottom surface, wherein the top surface is positioned opposite to the bottom surface;
forming a cleave layer on the dielectric layer that covers the top surface of the carrier wafer;
forming a silicon layer (Si) over the cleave layer;
coupling the Si layer to a handle wafer, wherein the handle wafer comprises silicon and wherein the handle wafer includes at least one cavity, wherein the Si layer encloses the at least one cavity; and
separating the carrier wafer from the handle wafer, wherein the separating forms a first wafer and a second wafer, wherein the first wafer comprises the handle wafer and the Si layer and a portion of the cleave layer, and wherein the second wafer is a reusable carrier wafer.

2. The method of claim 1, wherein the reusable carrier wafer comprises the carrier wafer, the dielectric layer and a second portion of the cleave layer.

3. The method of claim 1 further comprising:
forming a silicon dioxide (SiO₂) layer directly on the cleave layer; and
patterning the SiO₂ layer to expose at least one region of the cleave layer, wherein the Si layer is formed directly over the patterned SiO₂ layer.

4. The method of claim 3 further comprising forming Si layer directly on the at least one region to form a standoff in the first wafer.

5. The method of claim 3 further comprising forming a plurality of bump patterns on the patterned SiO₂ layer and before forming the Si layer over the patterned SiO₂ layer.

6. The method of claim 2 further comprising:
subsequent to the separating the carrier wafer from the handle wafer, removing the first portion of the cleave layer from the first wafer; and
subsequent to the separating the carrier wafer from the handle wafer, removing the SiO₂ layer from the first wafer.

7. The method of claim 1, wherein the separating comprises:
shining an infrared light onto the handle wafer and the carrier wafer after the Si layer is coupled to the handle wafer.

8. The method of claim 1, wherein the cleave layer comprises Titanium (Ti) or Tungsten (W).

9. The method of claim 1, wherein the carrier wafer comprises silicon.

10. The method of claim 1, wherein the carrier wafer comprises glass.

11. The method of claim 10, wherein the separating comprises:
shining a visible light onto the handle wafer and the carrier wafer after the Si layer is coupled to the handle wafer, wherein the shining weakens the cleave layer; and
mechanical cleaving the first wafer from the second wafer.

12. The method of claim 1, wherein the coupling is fusion bonding the Si layer to an oxide layer of the handle wafer.

13. A method comprising:
forming a thermal oxide layer on a carrier wafer with a top surface and a bottom surface, wherein the top surface is positioned opposite to the bottom surface;
forming a cleave layer on the thermal oxide layer that covers the top surface of the carrier wafer;
forming a silicon dioxide (SiO₂) layer directly on the cleave layer;
patterning the SiO₂ layer to expose at least one region of the cleave layer;
forming a silicon layer (Si) over the at least one region of the cleave layer and further over the patterned SiO₂ layer;
coupling the Si layer to a handle wafer, wherein the handle wafer comprises silicon and wherein the handle wafer includes at least one cavity, wherein the Si layer encloses the at least one cavity; and
separating the carrier wafer from the handle wafer, wherein the separating forms a first wafer and a second wafer, wherein the first wafer comprises the handle wafer and the Si layer and the patterned SiO₂ layer and a first portion of the cleave layer,
wherein the second wafer comprises the thermal oxide layer and a second portion of the cleave layer.

14. The method of claim 13, further comprising:
forming a plurality of bump patterns on the patterned SiO₂ layer and before forming the Si layer over the patterned SiO₂ layer.

15. The method of claim 13 further comprising:
subsequent to the separating the carrier wafer from the handle wafer, removing the first portion of the cleave layer from the first wafer; and
subsequent to the separating the carrier wafer from the handle wafer, removing the SiO₂ layer from the first wafer, wherein the silicon layer covering the at least one region forms a standoff region on the first wafer.

16. The method of claim 13, wherein the separating comprises:
shining an infrared light onto the handle wafer and the carrier wafer after the Si layer is coupled to the handle wafer, wherein the shining weakens the cleave layer; and
mechanical cleaving the first wafer from the second wafer.

17. The method of claim 13, wherein the cleave layer comprises Titanium (Ti) or Tungsten (W).

18. The method of claim 13, wherein the carrier wafer comprises silicon or glass.

19. The method of claim 13, wherein the separating comprises:
shining a visible light onto the handle wafer and the carrier wafer, and wherein the shining is subsequent to the Si layer being coupled to the handle wafer, wherein the shining weakens the cleave layer; and
mechanical cleaving the first wafer from the second wafer.

20. A method comprising:
forming a thermal oxide layer on a first carrier wafer with a top surface and a bottom surface, wherein the top surface is positioned opposite to the bottom surface;
forming a cleave layer on the thermal oxide layer that covers the top surface of the first carrier wafer;
forming a silicon layer (Si) over the cleave layer;
forming a handle layer, wherein the handle layer has a first side and a second side, and wherein the first side of the handle layer faces the silicon layer and wherein the second side of the handle layer faces away from the silicon layer;
attaching a second carrier wafer to the second side of the handle layer; and
separating the first carrier wafer from the handle wafer, wherein the separating forms a first wafer and a second wafer, wherein the first wafer comprises the handle wafer and the Si layer and a portion of the cleave layer, and wherein the second wafer is a reusable carrier wafer.

21. The method of claim 20 further comprising:
forming first silicon dioxide (SiO₂) layer, the silicon layer and a sacrificial silicon dioxide directly over the cleave layer;
patterning the sacrificial SiO₂ layer and depositing polysilicon layer over the silicon layer;
etching release holes in the polysilicon layer; and
removing the sacrificial Silicon dioxide layer and depositing the handle layer.

22. The method of claim 21, patterning the Silicon layer to form standoffs.

23. The method of claim 22, depositing Ge on the standoff and eutectic bonding to a silicon substrate.

24. The method of claim 23, removing the second carrier layer using light irradiation after the bonding.
